(19) United States
(12) Patent Application Publication
(10) Pub. No.: US 2025/0017021 A1
(43) Pub. Date: Jan. 9, 2025

(54) SEMICONDUCTOR MEMORY DEVICES AND MANUFACTURING METHODS THEREOF

(71) Applicant: SAMSUNG ELECTRONICS CO., LTD., Suwon-si (KR)

(72) Inventors: Seulji SONG, Suwon-si (KR); Suhyun BANG, Suwon-si (KR); Hwayeong LEE, Suwon-si (KR)

(21) Appl. No.: 18/630,647

(22) Filed: Apr. 9, 2024

(30) Foreign Application Priority Data
Jul. 5, 2023 (KR) 10-2023-0087409

(51) Int. Cl. H10B 53/30; H10B 53/20

(52) U.S. Cl. CPC H10B 53/30; H10B 53/20

(57) ABSTRACT

An integrated circuit device including first and second vertical transistors, wherein the first and second vertical transistors are apart from each other in a first direction; a common plate between the first and second vertical transistors; a first capacitor structure between the first vertical transistor and the common plate including a first lower electrode extending in the first direction, a first dielectric layer on the first lower electrode, and a first upper electrode on the first dielectric layer; and a second capacitor structure between the second vertical transistor and the common plate including a second lower electrode extending in the first direction, a second dielectric layer on the second lower electrode, and a second upper electrode on the second dielectric layer, wherein the first upper electrode is on a lower surface of the common plate, and the second upper electrode is on an upper surface of the common plate.

### CROSS-REFERENCE TO RELATED APPLICATION

This application is based on and claims priority under 35 USC § 119 to Korean Patent Application No. 10-2023-0087409, filed on Jul. 5, 2023, in the Korean Intellectual Property Office, the disclosure of which is incorporated by reference herein in its entirety.

### BACKGROUND

The inventive concept of the present disclosures relates to semiconductor memory devices, and more particularly, to semiconductor memory devices including a transistor and a capacitor corresponding to the transistor.

As semiconductor memory devices have become increasingly highly integrated, individual circuit patterns have been more miniaturized in order to implement more semiconductor memory devices in the same area. That is, as the degree of integration of semiconductor memory devices has increased, design rules for components of semiconductor memory devices have decreased.

In highly-scaled semiconductor memory devices, a process of forming a capacitor has become increasingly complicated and difficult. Capacitors employing conventionally known structures in miniaturized semiconductor devices face increasing hardship in securing desired capacitance.

### SUMMARY

The inventive concept of the present disclosures may provide semiconductor memory devices having a capacitor having improved performance and reliability.

The problems to be solved by the inventive concept of the present disclosures are not limited to the problems mentioned above, and other problems not mentioned will be clearly understood by those skilled in the art from the description below.

According to an aspect of the inventive concept, there is provided an integrated circuit device including a substrate; a first vertical transistor on an upper surface of the substrate;
a second vertical transistor on the first vertical transistor, wherein the first vertical transistor and the second vertical transistor are spaced apart from each other in a first direction that is perpendicular to the upper surface of the substrate; a common plate between the first vertical transistor and the second vertical transistor, wherein the common plate extends in a second direction that is parallel with the upper surface of the substrate; a first capacitor structure between the first vertical transistor and the common plate, wherein the first capacitor structure includes a first lower electrode that extends in the first direction, a first dielectric layer on the first lower electrode, and a first upper electrode on the first dielectric layer; and a second capacitor structure between the second vertical transistor and the common plate, wherein the second capacitor structure includes a second lower electrode that extends in the first direction, a second dielectric layer on the second lower electrode, and a second upper electrode on the second dielectric layer, wherein the first upper electrode is on a lower surface of the common plate, and the second upper electrode is on an upper surface of the common plate.

According to another aspect of the inventive concept, there is provided an integrated circuit device including a substrate; a first bit line that extends in a first direction on an upper surface of the substrate; a second bit line that extends in the first direction on the first bit line; a common plate between the first bit line and the second bit line; a first vertical transistor between the first bit line and the common plate; a second vertical transistor between the second bit line and the common plate; a first capacitor structure between the first vertical transistor and the common plate; a second capacitor structure between the second vertical transistor and the common plate; and an isolation insulating layer that extends in the common plate in a second direction and separates the first capacitor structure and the second capacitor structure from each other, wherein the first capacitor structure includes: a first lower electrode that extends in the second direction between the isolation insulating layer and the first vertical transistor; a first dielectric layer on a sidewall of the first lower electrode; and a first upper electrode on a sidewall of the first dielectric layer and a lower surface of the common plate, wherein the second direction is perpendicular to the upper surface of the substrate, wherein the first direction is parallel with the upper surface of the substrate, wherein the lower surface of the common plate is in contact with the first upper electrode, and wherein the first dielectric layer includes a ferroelectric material. According to another aspect of the inventive concept, there is provided an integrated circuit device including a substrate; a first bit line that extends in a first direction on an upper surface of the substrate; a second bit line that extends in the first direction on the first bit line; a common plate between the first bit line and the second bit line, wherein the common plate extends in the first direction; a plurality of first vertical transistors between the first bit line and the common plate; a plurality of second vertical transistors between the second bit line and the common plate; a first capacitor structure between one of the plurality of first vertical transistors and the common plate;
a second capacitor structure between one of the plurality of second vertical transistors and the common plate; and an isolation insulating layer between the first capacitor structure and the second capacitor structure, wherein the isolation insulating layer extends through the common plate in a second direction and separates the first capacitor structure and the second capacitor structure from each other, wherein the first capacitor structure includes: a plurality of first lower electrodes that extend in the second direction between the isolation insulating layer and the plurality of first vertical transistors and are arranged in the first direction, wherein each of the plurality of first lower electrodes has a tapered shape with a first diameter that decreases toward the plurality of first vertical transistors; a first dielectric layer on a sidewall of each of the plurality of first lower electrodes, wherein the first dielectric layer includes a ferroelectric material; and a first upper electrode on a sidewall of the first dielectric layer and a portion of a lower surface of the common plate, wherein the first upper electrode is in contact with the lower surface of the common plate, and wherein the second capacitor structure includes: a plurality of second lower electrodes that extend in the second direction between the isolation insulating layer and the plurality of second vertical transistors and are arranged in the first direction, wherein each of the plurality of second lower electrodes has a tapered shape with a second diameter that decreases toward the isolation insulating layer; a second dielectric layer on a sidewall of each of the plurality of second lower electrodes, wherein the second dielectric layer includes a ferroelectric material; and a second upper electrode on a sidewall of the second dielectric layer and a portion of an upper surface of the common plate, wherein the second upper electrode is in contact with the upper surface of the common plate wherein the second direction is perpendicular to the upper surface of the substrate, and wherein the first direction is parallel with the upper surface of the substrate.

### BRIEF DESCRIPTION OF THE DRAWINGS

Embodiments will be more clearly understood from the following detailed description taken in conjunction with the accompanying drawings in which:

FIG. 1 is an equivalent circuit diagram illustrating a cell array of a semiconductor memory device according to some embodiments;

FIG. 2 is a layout diagram of a semiconductor memory device according to some embodiments;

FIG. 3 is a cross-sectional view taken along line X1-X1′ of FIG. 2;

FIG. 4A is an enlarged view of portion P1 of FIG. 3;

FIG. 4B is an enlarged view of a semiconductor memory device according to some embodiments, which is an enlarged view of a portion corresponding to portion P1 of FIG. 3;

FIG. 4C is an enlarged view of a semiconductor memory device according to some embodiments, which is an enlarged view of a portion corresponding to portion P1 of FIG. 3; and

FIG. 5 is a cross-sectional view of a semiconductor memory device according to some embodiments, taken along line X1-X1′ of FIG. 2;

FIG. 6 is a cross-sectional view of a semiconductor memory device according to some embodiments, taken along line X1-X1′ of FIG. 2; and

FIGS. 7 to 17 are cross-sectional views illustrating a method of manufacturing the semiconductor memory device shown in FIGS. 1 to 3.

### DETAILED DESCRIPTION OF THE EMBODIMENTS

Hereinafter, embodiments are described in detail with reference to the accompanying drawings. However, the inventive concept of the present disclosures does not have to be configured as limited to the embodiments described below and may be embodied in various other forms. It therefore will be understood that the following embodiments are just illustrative but not limitative in all aspects.

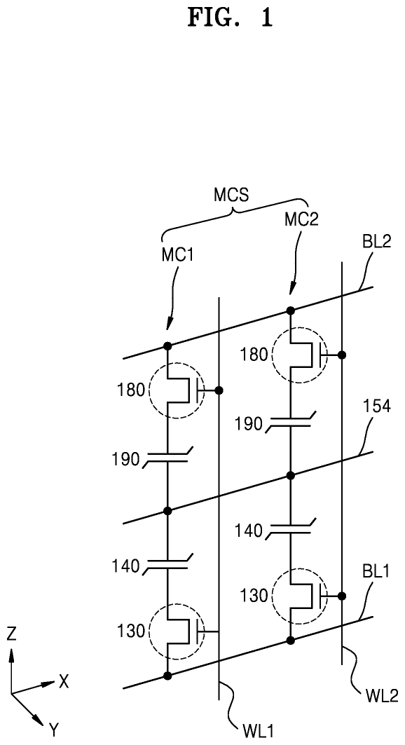

FIG. 1 is an equivalent circuit diagram illustrating a cell array MCS of a semiconductor memory device according to some embodiments.

Referring to FIG. 1, the cell array MCS of a semiconductor memory device according to some embodiments may include a plurality of memory cells MC1 and MC2. Although FIG. 1 illustrates that the memory cells MC1 and MC2 are arranged in a first horizontal direction (an X direction), this is for convenience of illustration, and the memory cells MC1 and MC2 may be arranged in columns and rows in the first horizontal direction (the X direction) and/or a second horizontal direction (a Y direction) different from the first horizontal direction (the X direction). In some embodiments, the second horizontal direction (the Y direction) may be orthogonal to the first horizontal direction (the X direction). In some other embodiments, the second horizontal direction (the Y direction) may be a direction extending at an acute angle with the first horizontal direction (the X direction). The first and the second horizontal directions may be parallel with an upper surface of a substrate 110, which will be described below. As shown in FIG. 1, the memory cells MC1 and MC2 may include a first memory cell MC1 and a second memory cell MC2 arranged side by side in the first horizontal direction (the X direction). Spatially relative terms, such as “beneath,” “below,” “lower,” “above,” “upper,” “higher” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

Each of the memory cells MC1 and MC2 may be two transistors two capacitors (2T2C) memory cell including two transistors and two capacitors. Each of a plurality of capacitors included in the memory cells MC1 and MC2 may be a ferroelectric capacitor. For example, each of the memory cells MC1 and MC2 may be a two transistors two ferroelectric capacitors (2T2CFE) memory cell including two transistors and a plurality of (e.g., two or more) ferroelectric capacitors, and the semiconductor memory device having the cell array MCS including the memory cells MC1 and MC2 may be referred to as a two transistors two capacitors ferroelectric random access memory (2T2C FeRAM).

Each of the memory cells MC1 and MC2 may include a first vertical transistor 130, a second vertical transistor 180, a first capacitor structure 140, and a second capacitor structure 190. The first capacitor structure 140 and the second capacitor structure 190 included in each of the memory cells MC1 and MC2 may be arranged to be stacked with the first vertical transistor 130 and the second vertical transistor 180 in a vertical direction (a Z direction). The first capacitor structure 140 and the second capacitor structure 190 may be arranged between the first vertical transistor 130 and the second vertical transistor 180 in the vertical direction. The vertical direction may be a third direction that is perpendicular to the first and second horizontal directions. The vertical direction may be perpendicular to the upper surface of the substrate.

The first vertical transistor 130, the second vertical transistor 180, the first capacitor structure 140, and the second capacitor structure 190 may be arranged in the vertical direction (the Z direction). For example, the first vertical transistor 130, the first capacitor structure 140, the second capacitor structure 190, and the second vertical transistor 180 may be sequentially arranged (e.g., stacked) in the vertical direction (the Z direction). Although in FIG. 1 two first vertical transistors 130, two second vertical transistors 180, two first capacitor structures 140, and two second capacitor structures 190 are shown, the inventive concept of the present disclosures is not limited thereto.

First and second bit lines BL1 and BL2 may be connected (e.g., electrically connected) to sources of the first vertical transistor 130 and the second vertical transistor 180, respectively. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. For example, an “electrical connection” between element A and element B may include a direct physical connection between element A and element B and/or an indirect physical connection between element A and element B with one or more intervening elements therebetween. The first vertical transistor 130 and the first capacitor structure 140 may be connected (e.g., electrically connected) in series, and the second vertical transistor 180 and the second capacitor structure 190 may be connected (e.g., electrically connected) in series. The first and second vertical transistors 130 and 180 may be connected (e.g., electrically connected) to one end of the first capacitor structure 140 and one end of the second capacitor structure 190, respectively, and a common plate 154 may be connected (e.g., electrically connected) to the other ends (e.g., opposite to the one end) of the first and second capacitor structures 140 and 190. Each of the first capacitor structure 140 and the second capacitor structure 190 may include a ferroelectric dielectric film, and bi-directional electric field application may change a polarization direction of the ferroelectric material in the ferroelectric dielectric film. Therefore, a separate conductive interconnection is required to independently apply an electric field to an upper electrode of each of the first capacitor structure 140 and the second capacitor structure 190. Through the common plate 154, an electric field may be applied to the upper electrode of each of the first capacitor structure 140 and the second capacitor structure 190. A first word line WL1 may be connected (e.g., electrically connected) to gate terminals of the first vertical transistor 130 and the second vertical transistor 180 included in the first memory cell MC1 to apply a voltage to the gate terminals. In addition, a second word line WL2 may be connected (e.g., electrically connected) to gate terminals of the first vertical transistor 130 and the second vertical transistor 180 included in the second memory cell MC2 arranged side-by-side with the first memory cell MC1 in the first horizontal direction (the X direction) to apply a voltage thereto.

Each of the first and second capacitor structures 140 and 190 may have a positive polarization or a negative polarization. Voltage applied to the gate of the first vertical transistor 130 or the second vertical transistor 180 may vary depending on a polarization direction of each of the first and second capacitor structures 140 and 190 included in the memory cells MC1 and MC2. For example, when the first memory cell MC1 includes the first capacitor structure 140 and the second capacitor structure 190, there may be three states including two positive polarizations, one positive polarization and one negative polarization, and two negative polarizations. If the number of capacitor structures included in the first memory cell MC1 increases, more information may be stored in the first memory cell MC1.

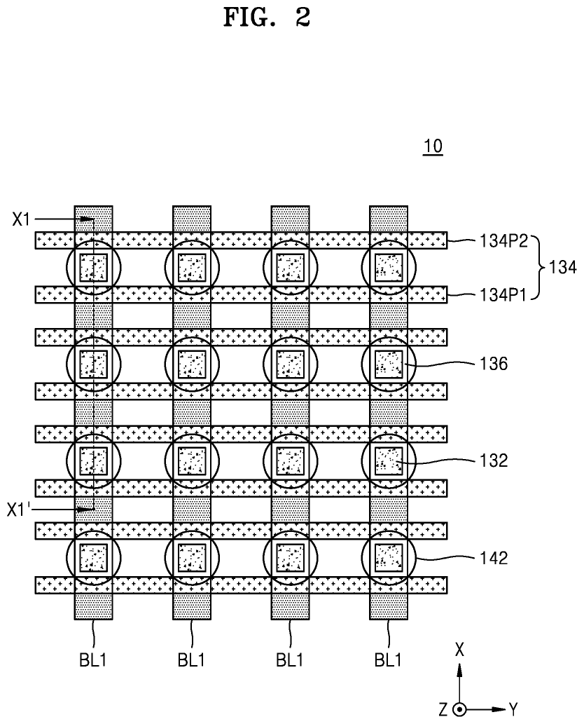

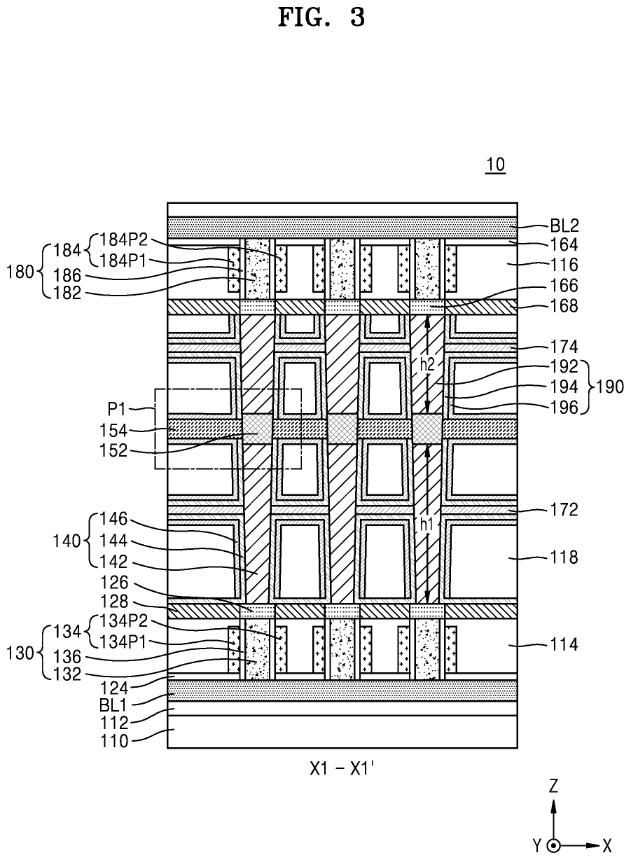

FIG. 2 is a layout diagram of a semiconductor memory device 10 according to some embodiments, and FIG. 3 is a cross-sectional view taken along line X1-X1′ of FIG. 2.

Referring to FIGS. 2 and 3, the semiconductor memory device 10 may include a substrate 110, a plurality of first bit lines BL1, a plurality of second bit lines BL2, first and second vertical transistors 130 and 180, first and second capacitor structures 140 and 190, and a common plate 154. The vertical transistor (e.g., the first and second vertical transistors 130 and 180) referred to herein may be a vertical channel transistor (VCT) having a structure in which a channel layer extends in a vertical direction (e.g., the Z direction). The VCT may refer to a structure in which channel lengths of first and second channel layers 132 and 182, which will be described below, extend in the vertical direction.

A lower insulating layer 112 may be disposed on the substrate 110, and the plurality of first bit lines BL1 may be spaced apart from each other in the second horizontal direction (the Y direction) and extend long in the first horizontal direction (the X direction) on the lower insulating layer 112.

According to some embodiments, the plurality of second bit lines BL2 may be spaced apart from each other in the second horizontal direction (the Y direction) and extend long in the first horizontal direction (the X direction). Also, a first bit line BL1 among the plurality of first bit lines BL1 and a second bit line BL2 among the plurality of second bit lines BL2 may be spaced apart from each other in the vertical direction (the Z direction). In embodiments, the first and second bit lines BL1 and BL2 may include, for example, doped polysilicon, metal, conductive metal nitride, conductive metal silicide, conductive metal oxide, and/or combinations thereof. For example, the first and second bit lines BL1 and BL2 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, and/or combinations thereof, but are not limited thereto. The each of first and second bit lines BL1 and BL2 may include a single layer or multi layers of the aforementioned materials. In embodiments, the first and second bit lines BL1 and BL2 may include a 2D semiconductor material, and the 2D semiconductor material may include, for example, graphene, carbon nanotubes, and/or combinations thereof.

According to some embodiments, the first and second vertical transistors 130 and 180 may be spaced apart from each other in the vertical direction (the Z direction) between the first bit line BL1 and the second bit line BL2. As is described below, the common plate 154 may be located between the first vertical transistor 130 and the second vertical transistor 180 to serve as a boundary physically separating the first vertical transistor 130 and the first capacitor structure 140 from the second vertical transistor 180 and the second capacitor structure 190. The common plate 154 may extend in a horizontal direction (e.g., the first horizontal direction). Here, the first vertical transistor 130 may be spaced apart from the common plate 154 in the vertical direction (the Z direction). The first vertical transistor 130 may be between the first bit line BL1 and the common plate 154. The second vertical transistor 180 may be spaced apart from the common plate 154 in the vertical direction (the Z direction). The second vertical transistor 180 may be between the second bit line BL1 and the common plate 154.

According to some embodiments, the first vertical transistor 130 may include a first channel layer 132 extending in the vertical direction (the Z direction). The first channel layer 132 may be connected (e.g., electrically connected) to the first bit line BL1. For example, a lower surface of the first channel layer 132 may be in contact with an upper surface of the first bit line BL1. The first vertical transistor 130 may include a first gate electrode 134 on a sidewall (e.g., on opposite sidewalls) of the first channel layer 132, and a first gate insulating layer 136 on (e.g., extending around or surrounding) the sidewall (e.g., sidewalls or side circumference) of the first channel layer 132. The first gate insulating layer 136 may be between the first channel layer 132 and the first gate electrode 134. The second vertical transistor 180 may include a second channel layer 182 extending in the vertical direction (the Z direction). The second channel layer 182 may be connected (e.g., electrically connected) to the second bit line BL2. For example, an upper surface of the second channel layer 182 may be in contact with a lower surface of the second bit line BL2. The second vertical transistor 180 may include a second gate electrode 184 on a sidewall (e.g., on opposite sidewalls) of the second channel layer 182, and a second gate insulating layer 186 on (e.g., extending around or surrounding) the sidewall (e.g., sidewalls or side circumference) of the second channel layer 182. The second gate insulating layer 186 may be between the second channel layer 182 and the second gate electrode 184.

The first channel layers 132 may be spaced apart from each other in the first horizontal direction (the X direction) and the second horizontal direction (the Y direction) on the first bit line BL1 in, for example, a matrix form, and the second channel layers 182 may be spaced apart from each other in the first horizontal direction (the X direction) and the second horizontal direction (the Y direction) on the second bit line BL2, in, for example, a matrix form. The first channel layer 132 and the second channel layer 182 may have a first width in the first horizontal direction (the X direction) and a first height in the vertical direction (the Z direction), and the first height may be greater than the first width. For example, the first height may be about 2 to 10 times the first width, but is not limited thereto. A lower portion of each of the first channel layer 132 and the second channel layer 182 may be configured to function as a first source/drain region (not shown), an upper portion of each of the first channel layer 132 and the second channel layer 182 may be configured to function as a second source/drain region (not shown), and a portion of the first channel layer 132 and the second channel layer 182 between the first and second source/drain regions may be configured to function as a channel region (not shown).

In embodiments, the first channel layer 132 and the second channel layer 182 may include, for example, an oxide semiconductor, and the oxide semiconductor may include, for example, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, and/or combinations thereof. Each of the first channel layer 132 and the second channel layer 182 may include a single layer or multi layers of the oxide semiconductor. In some examples, the first channel layer 132 and the second channel layer 182 may have bandgap energy greater than that of silicon. For example, the first channel layer 132 and the second channel layer 182 may have bandgap energy of about 1.5 eV to about 5.6 cV (e.g., 1.5 eV to 5.6 eV). For example, the first channel layer 132 and the second channel layer 182 may have bandgap energy of about 2.0 eV to about 4.0 cV (e.g., 2.0 eV to 4.0 cV). In some embodiments, the first channel layer 132 and the second channel layer 182 may include polycrystalline and/or amorphous but are not limited thereto. In embodiments, the first channel layer 132 and the second channel layer 182 may include a 2D semiconductor material, and the 2D semiconductor material may include, for example, graphene, carbon nanotube, and/or combinations thereof.

According to some embodiments, the first gate electrode 134 of the first vertical transistor 130 may extend in the second horizontal direction (the Y direction). The first gate electrode 134 may include a first sub-gate electrode 134P1 facing a first sidewall of the first channel layer 132 and a second sub-gate electrode 134P2 facing a second sidewall opposite to the first sidewall of the first channel layer 132. As one first channel layer 132 is located between the first sub-gate electrode 134P1 and the second sub-gate electrode 134P2, the first vertical transistor 130 may have a dual-gate transistor structure. However, the inventive concept of the present disclosures is not limited thereto, and in the first vertical transistor 130, one of the first and second sub-gate electrodes 134P1 and 134P2 may be omitted and only the other one of the first and second sub-gate electrodes 134P1 and 134P2 facing the first or second sidewall of the first channel layer 132 may be formed to have a single-gate transistor structure. Similarly, the second gate electrode 184 of the second vertical transistor 180 may extend in the second horizontal direction (the Y direction). The second gate electrode 184 may include a third sub-gate electrode 184P1 facing a third sidewall of the second channel layer 182 and a fourth sub-gate electrode 184P2 facing a fourth sidewall opposite to the third sidewall of the second channel layer 182. As one second channel layer 182 is located between the third sub-gate electrode 184P1 and the fourth sub-gate electrode 184P2, the second vertical transistor 180 may have a dual-gate transistor structure. However, the inventive concept of the present disclosures is not limited thereto, and in the second vertical transistor 180, one of the third and fourth sub-gate electrodes 184P1 and 184P2 may be omitted and only the other one of the third and fourth sub-gate electrodes 184P1 and 184P2 facing the third or fourth sidewall of the second channel layer 182 may be formed to have a single-gate transistor structure.

The first and second gate electrodes 134 and 184 may include, for example, doped polysilicon, metal, conductive metal nitride, conductive metal silicide, conductive metal oxide, and/or combinations thereof. For example, the first and second gate electrodes 134 and 184 may include doped polysilicon, Al, Cu, Ti, Ta, Ru, W, Mo, Pt, Ni, Co, TiN, TaN, WN, NbN, iAl, TiAlN, TiSi, TiSiN, TaSi, TaSIN, RuTiN, NiSi, CoSi, IrOₓ, RuOₓ, and/or combinations thereof but are not limited thereto.

The first gate insulating layer 136 of the first vertical transistor 130 may extend around (e.g., surround) the sidewall (e.g., the sidewalls or the side circumference) of the first channel layer 132 and may be located between the first channel layer 132 and the first gate electrode 134. For example, as shown in FIG. 2, the entire sidewalls of the first channel layer 132 may be surrounded by the first gate insulating layer 136, and a portion of the sidewall of the first gate electrode 134 may contact the first gate insulating layer 136. For example, the first gate insulating layer 136 may extend in an extension direction (e.g., the second horizontal direction (the Y direction)) of the first gate electrode 134, and only two (e.g., opposite) sidewalls facing the first gate electrode 134, among the sidewalls of the first channel layer 132, may contact the first gate insulating layer 136. Similarly, the second gate insulating layer 186 of the second vertical transistor 180 may extend around (e.g., surround) the sidewall (e.g., the sidewalls or the side circumference) of the second channel layer 182 and may be located between the second channel layer 182 and the second gate electrode 184. For example, the entire sidewalls of the second channel layer 182 may be surrounded by the second gate insulating layer 186, and a portion of the sidewall of the second gate electrode 184 may contact the second gate insulating layer 186. For example, the second gate insulating layer 186 may extend in an extension direction (e.g., the second horizontal direction (the Y direction)) of the second gate electrode 184, and only two (e.g., opposite) sidewalls facing the second gate electrode 184, among the sidewalls of the second channel layer 182, may contact the second gate insulating layer 186.

In embodiments, the first and second gate insulating layers 136 and 186 may include, for example, a silicon oxide film, a silicon oxynitride film, a high-k film having a dielectric constant higher than that of the silicon oxide film, and/or combinations thereof. The high-k film may include, for example, metal oxide and/or metal oxynitride. For example, the high-k film usable as the first and second gate insulating layers 136 and 186 may include HfO₂, HfSiO, HfSiON, HfTaO, HfTiO, HfZrO, ZrO₂, Al₂O₃, and/or combinations thereof but is not limited thereto.

According to some embodiments, a first buried layer 124 and a first buried insulating layer 114 may be located in a space between two adjacent first channel layers 132. The first buried layer 124 may be on an upper surface of the first bit line BL1. The first buried insulating layer 114 may be on an upper surface of the first buried layer 124. The first buried layer 124 may be disposed in a lower portion of the space between the two adjacent first channel layers 132, and the first buried insulating layer 114 may be formed to fill the rest of the space between the two adjacent first vertical transistors 130 on the first buried layer 124. In some embodiments, the first buried layer 124 may be on (e.g., cover or overlap) a portion (e.g., a lower portion) of the sidewall of the first gate insulating layer 136 and an upper surface of the first bit line BL1 and have a constant (a uniform) thickness along an upper surface of the first bit line BL1. The first buried insulating layer 114 may be on (e.g., cover or overlap) sidewalls and an upper surface of the first gate electrode 134 and an upper surface of the first buried layer 124 and may extend along the upper surface of the first buried layer 124. An upper surface of the first buried insulating layer 114 may be at the same vertical level as that of an upper surface of the first channel layer 132. According to embodiments, the first buried layer 124 and the first buried insulating layer 114 may be formed as a continuous material layer. A continuous material layer herein may refer to a structure without a visible boundary between sub-structures thereof.

Similarly, the second buried layer 164 and the second buried insulating layer 116 may be arranged in a space between two adjacent second channel layers 182. The second buried layer 164 may be on a lower surface of the second bit line BL2, and the second buried insulating layer 116 may be on a lower surface of the second buried layer 164. The second buried layer 164 is disposed at the upper portion of the space between the two adjacent second channel layers 182, and the second buried insulating layer 116 may be formed to fill the rest of the space between two adjacent second vertical transistors 180 on the second buried layer 164. In some embodiments, the second buried layer 164 may be on (e.g., cover or overlap) a portion (e.g., an upper) of the sidewall of the second gate insulating layer 186 and a lower surface of the second bit line BL2 and have a constant (a uniform) thickness along the lower surface of the second bit line BL2. The second buried insulating layer 116 may be on (e.g., cover or overlap) sidewalls and a lower surface of the second gate electrode 184 and the lower surface of the second buried layer 164 and may extend along the lower surface of the second buried layer 164. A lower surface of the second buried insulating layer 116 may be at the same vertical level as that of a lower surface of the second channel layer 182. According to embodiments, the second buried layer 164 and the second buried insulating layer 116 may be formed as a continuous material layer. According to some embodiments, the first buried layer 124, the second buried layer 164, the first buried insulating layer 114, and the second buried insulating layer 116 may include, for example, silicon oxide.

According to some embodiments, the semiconductor memory device 10 may include a first landing pad 126 and a first upper insulating layer 128 located between the first vertical transistor 130 and the first capacitor structure 140. The first landing pad 126 may be disposed on (the upper surface of) the first channel layer 132. The first landing pad 126 may be disposed to vertically overlap the first channel layer 132 and may be spaced apart from another first landing pad 126 in the first horizontal direction (the X direction) and the second horizontal direction (the Y direction) in a matrix form. The first upper insulating layer 128 may extend around (e.g., surround) sidewalls of the first landing pad 126 on (the upper surface of) the first buried insulating layer 114. As used herein, “an element A overlapping an element B in a direction X” (or similar language) means that there is at least one line that extends in the direction X and intersects both the elements A and B.

In some embodiments, the semiconductor memory device 10 may include a second landing pad 166 and a second upper insulating layer 168 located between the second vertical transistor 180 and the second capacitor structure 190. The second landing pad 166 may be disposed on (the lower surface of) the second channel layer 182. The second landing pad 166 may be disposed to vertically overlap the second channel layer 182 and may be spaced apart from another second landing pad 166 in the first horizontal direction (the X direction) and the second horizontal direction (the Y direction) in a matrix form. The second upper insulating layer 168 may extend around (e.g., surround) sidewalls of the second landing pad 166 on (the lower surface of) the second buried insulating layer 116.

The first and second landing pads 126 and 166 may include, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, and/or combinations thereof but are not limited thereto.

According to some embodiments, the first capacitor structure 140 may be disposed on (the upper surface of) the first landing pad 126 and (the upper surface of) the first upper insulating layer 128. The first capacitor structure 140 may include a first lower electrode 142 disposed to vertically overlap the first landing pad 126 and extending in the vertical direction (the Z direction), a first dielectric layer 144 disposed on (e.g., conformally covering or overlapping) a sidewall of the first lower electrode 142, and a first upper electrode 146 disposed on (e.g., conformally covering or overlapping) a sidewall of the first dielectric layer 144. In some embodiments, the semiconductor memory device 10 may further include a first support plate 172 located at an intermediate point in the vertical direction (the Z direction) of the first capacitor structure 140 and extending to be flat in a direction parallel to the upper surface of the substrate 110. For example, the first support plate 172 may be between the first upper insulating layer 128 and the common plate 154. The first support plate 172 may extend in a horizontal direction (e.g., the first horizontal direction) between the first dielectric layers 144 to contact the sidewall of the first lower electrode 142.

The first lower electrode 142 may also be disposed to vertically overlap the first channel layer 132 and may have a tapered shape having a diameter narrowing (decreasing) toward the substrate 110 in the first vertical direction (the Z direction). In this case, a length of the first lower electrode 142 in the vertical direction (the Z direction) may be relatively much longer than a diameter of the first lower electrode 142 in a horizontal direction (e.g., the X direction and/or the Y direction). A plurality of first lower electrodes 142 may be formed, and the first lower electrodes 142 may be arranged at regular intervals in the first horizontal direction (the X direction) and/or the second horizontal direction (the Y direction). The first lower electrode 142 may be formed through (e.g., may extend through or may penetrate) the first support plate 172 (in the vertical direction).

The first dielectric layer 144 may be on (e.g., conformally cover or overlap) the upper and lower surfaces of the first support plate 172 and the sidewalls of the first lower electrode 142. The first dielectric layer 144 may have a uniform thickness in a direction less than that of the first lower electrode 142. In some embodiments, the first dielectric layer 144 may be conformally on (e.g., conformally cover or overlap) the upper surface of the first upper insulating layer 128 as well.

The first upper electrode 146 may be on (e.g., conformally cover or overlap) a surface of the first dielectric layer 144 and the lower surface of the common plate 154. As shown in FIG. 3, a portion of the first dielectric layer 144 that covers (or overlaps) the upper surface of the first upper insulating layer 128 may be at least partially exposed by the first upper electrode 146. However, according to some embodiments, the first upper electrode 146 may be on a portion of the first dielectric layer 144 covering (or overlapping) the upper surface of the first upper insulating layer 128. The first upper electrode 146 may face the first lower electrode 142 with the first dielectric layer 144 therebetween.

According to some embodiments, a second capacitor structure 190 may be located between the second landing pad 166 and the first capacitor structure 140. Here, as shown in FIG. 3, in the space between the first vertical transistor 130 and the second vertical transistor 180 in the vertical direction (the Z direction), the space occupied by the second capacitor structure 190 may be smaller than the space occupied by the first capacitor structure 140. For example, a height of the first capacitor structure 140 in the vertical direction may be taller than that of the second capacitor structure 190. The second capacitor structure 190 may include a second lower electrode 192 that vertically overlaps the first landing pad 126 and the second landing pad 166 and extends in the vertical direction (the Z direction), a second dielectric layer 194 disposed on (e.g., conformally covering or overlapping) a sidewall of the second lower electrode 192, and a second upper electrode 196 disposed on (e.g., conformally covering or overlapping) a sidewall of the second dielectric layer 194. In some embodiments, the semiconductor memory device 10 may further include a second support plate 174 located at an intermediate point of the second capacitor structure 190 in the vertical direction (the Z direction) and extending to be flat in a direction parallel to the upper surface of the substrate 110. For example, the second support plate 174 may be between the second upper insulating layer 168 and the common plate 154. The second support plate 174 may extend in a horizontal direction (e.g., the first horizontal direction) between the second dielectric layers 194 to contact the sidewall of the second lower electrode 192.

The second lower electrode 192 may be disposed to vertically overlap the second channel layer 182 and have a tapered shape having a diameter narrowing (decreasing) toward the substrate 110 in the vertical direction (the Z direction). Here, a length of the second lower electrode 192 in the vertical direction (the Z direction) may be relatively much longer than a diameter of the second lower electrode 192 in a horizontal direction (e.g., the X direction and/or the Y direction). A plurality of second lower electrodes 192 may be formed, and the second lower electrodes 192 may be arranged at regular intervals in the first horizontal direction (the X direction) and/or the second horizontal direction (the Y direction). The second lower electrode 192 may be formed through (e.g., may extend through or may penetrate) the second support plate 174 (in the vertical direction).

The second dielectric layer 194 may be on (e.g., conformally cover or overlap) the upper and lower surfaces of the second support plate 174 and the sidewalls of the second lower electrode 192. The second dielectric layer 194 may have a uniform thickness in a direction less than that of the second lower electrode 192. The second dielectric layer 194 may be on a lower surface of the second upper insulating layer 168. The lower surface of the second upper insulating layer 168 may have a portion exposed by the second dielectric layer 194.

The second upper electrode 196 may be on (e.g., conformally cover or overlap) a surface of the second dielectric layer 194 and an upper surface of the common plate 154. The second upper electrode 196 may face the second lower electrode 192 with the second dielectric layer 194 therebetween.

The semiconductor memory device 10 may further include an isolation insulating layer 152 located between the first lower electrode 142 and the second lower electrode 192. A lower surface of the isolation insulating layer 152 may contact the first lower electrode 142, and an upper surface of the isolation insulating layer 152 may contact the second lower electrode 192. A sidewall of the first lower electrode 142, a sidewall of the second lower electrode 192, and a sidewall of the isolation insulating layer 152 may be located on the (substantially) same plane without a (substantial) step difference. The isolation insulating layer 152 may structurally (e.g., physically and/or electrically) separate the first capacitor structure 140 from the second capacitor structure 190. The isolation insulating layer 152 may include an insulating material so that the first lower electrode 142 is electrically insulated from the second lower electrode 192. For example, the isolation insulating layer 152 may include silicon nitride.

According to some embodiments, a length h1 of the first lower electrode 142 (e.g., from the first landing pad 126 to the isolation insulating layer 152) in the vertical direction (the Z direction) may be longer than a length h2 of the second lower electrode 192 (e.g., from the isolation insulating layer 152 to the second landing pad 166) in the vertical direction (the Z direction). The first lower electrode 142 and the second lower electrode 192 shown in FIG. 3 may have a tapered shape having a diameter narrowing (decreasing) toward the substrate 110 in the vertical direction (the Z direction). Therefore, because an average diameter of the second lower electrode 192 is greater than that of the first lower electrode 142, in order to balance the electrical characteristics of the second capacitor structure 190 and the first capacitor structure 140, the length h2 of the second lower electrode 192 in the vertical direction (the Z direction) may be less than the length h1 of the first lower electrode 142 in the vertical direction (the Z direction).

According to some embodiment, the semiconductor memory device 10 may include a third buried insulating layer 118 filling an empty space between the first upper electrodes 146 of the first capacitor structure 140 and an empty space between the second upper electrodes 196 of the second capacitor structure 190. The third buried insulating layer 118 may include, for example, a silicon oxide film.

The first and second lower electrodes 142 and 192 may include, for example, a metal-containing film including a first metal. In embodiments, the first and second upper electrodes 146 and 196 may include the same metal as the first metal. In some embodiments, the first and second upper electrodes 146 and 196 may include a metal different from the first metal.

The first and second lower electrodes 142 and 192 and the first and second upper electrodes 146 and 196 may each include, for example, a metal film, a conductive metal oxide film, a conductive metal nitride film, a conductive metal oxynitride film, and/or combinations thereof. In embodiments, the first and second lower electrodes 142 and 192 and the first and second upper electrodes 146 and 196 may each include, for example, Ti, Ti oxide, Ti nitride, Ti oxynitride, Nb, Nb oxide, Nb nitride, Nb oxynitride, Co, Co oxide, Co nitride, Co oxynitride, Sn, Sn oxide, Sn nitride, Sn oxynitride, Hf, Hf oxide, Hf nitride, Hf oxynitride, and/or combinations thereof. For example, the first and second lower electrodes 142 and 192 and the first and second upper electrodes 146 and 196 may each include NbN, TIN, CON, SnO₂, and/or combinations thereof. In some embodiments, the first and second lower electrodes 142 and 192 and the first and second upper electrodes 146 and 196 may include TaN, TiAlN, TaAlN, W, Ru, RuO₂, SrRuO₃, Ir, IrO₂, Pt, PtO, SRO(SrRuO₃), BSRO((Ba,Sr)RuO₃), CRO(CaRuO₃), LSCO((La,Sr)CoO₃), and/or combinations thereof. However, the constituent materials of the first and second lower electrodes 142 and 192 and the first and second upper electrodes 146 and 196 are not limited to those mentioned above.

Each of the first and second lower electrodes 142 and 192 and the first and second upper electrodes 146 and 196 may have a thickness greater than 100 Å in a horizontal direction. In embodiments, the first and second lower electrodes 142 and 192 may each have a thickness in the horizontal direction greater than those of the first and second upper electrodes 146 and 196. However, according to embodiments, the inventive concept of the present disclosures is not limited thereto, and the thicknesses of the first and second lower electrodes 142 and 192 in the horizontal direction may be substantially equal to or less than the thicknesses of the first and second upper electrodes 146 and 196 in the horizontal direction.

The first and second dielectric layers 144 and 194 may include a material having ferroelectricity. Here, the first and second dielectric layers 144 and 194 may include, for example, lead zirconate titanate (PZT), strontium bismuth tantalate (SBT), and/or bismuth lanthanum titanate (BLT). In some embodiments, the first and second dielectric layers 144 and 194 may include, for example, hafnium oxide, hafnium zirconium oxide, zirconium oxide, barium strontium titanium oxide, barium titanium oxide, and/or lead zirconium titanium oxide. Here, hafnium zirconium oxide may be a material in which zirconium (Zr) is doped in hafnium oxide, or a compound of hafnium (Hf), zirconium (Zr), and oxygen (O). The first and second dielectric layers 144 and 194 may further include a doping element doped in the material described above. Doping elements may be, for example, an element selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn).

The first support plate 172 and the second support plate 174 may include, for example, silicon nitride. Also, the common plate 154 may include, for example, a carbon electrode having conductivity. For example, the carbon electrode may include amorphous carbon (aC). Because the common plate 154 has conductivity, the first upper electrode 146 of the first capacitor structure 140 and the second upper electrode 196 of the second capacitor structure 190 may be electrically connected to (e.g., electrically connected through) the common plate 154.

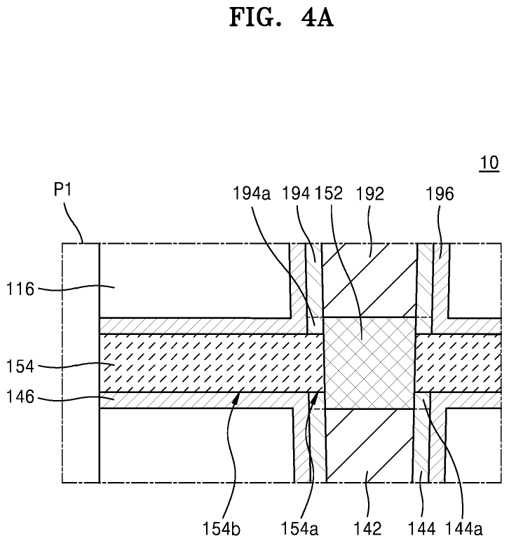

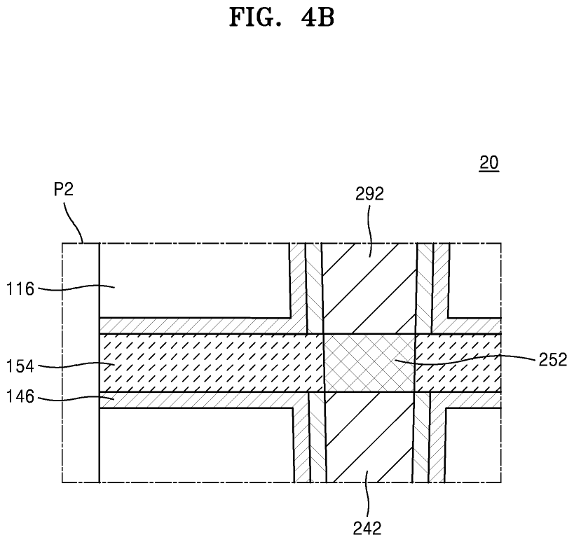

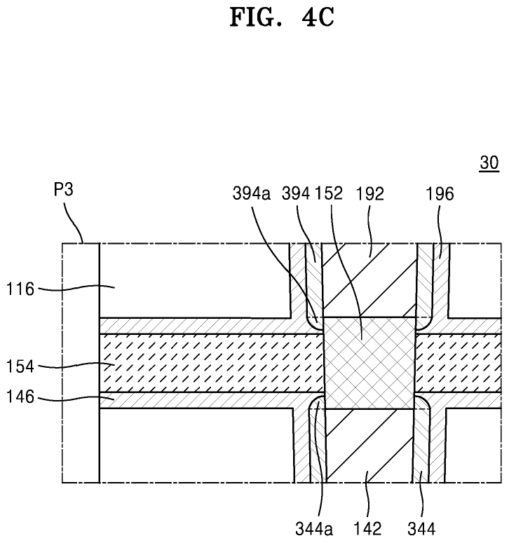

FIG. 4A is an enlarged view of portion P1 of FIG. 3.

Referring to FIG. 4A, the common plate 154 may include a first surface 154a contacting the first dielectric layer 144 and a second surface 154b contacting the first upper electrode 146. In this case, an area of the second surface 154b may be larger than that of the first surface 154a. Because a surface of the common plate 154 may be treated with hydrogen plasma, it may be difficult to deposit the first dielectric layer 144 including a dielectric material on the surface (e.g., the first surface 14a) of the common plate 154. Accordingly, an area of the second surface 154b in which the common plate 154 contacts the first upper electrode 146 may be larger than an area of the first surface 154a in which the common plate 154 contacts the first dielectric layer 144. Similarly, an area of a surface of the common plate 154 in contact with the second upper electrode 196 may be larger than an area of a surface of the common plate 154 in contact with the second dielectric layer 194.

Also, as shown in FIG. 4A, the first dielectric layer 144 may not be located between a lower surface of the common plate 154 and the first upper electrode 146. The first dielectric layer 144 may contact the lower surface of the common plate 154 and the first dielectric layer 144 may not grow on the lower surface of the common plate 154. This may mean that the first dielectric layer 144 may not be deposited relatively (e.g., may not be deposited or may be unlikely deposited) on the lower surface of the common plate 154 rather than on the side of the first lower electrode 142. The second dielectric layer 194 may not be located between the upper surface of the common plate 154 and the second upper electrode 196 (e.g., the lower surface of the second upper electrode 196). The second dielectric layer 194 may contact the upper surface of the common plate 154, and the second dielectric layer 194 may not grow on the upper surface of the common plate 154. This may mean that the second dielectric layer 194 may not be deposited relatively (e.g., may not be deposited or may be unlikely deposited) on the upper surface of the common plate 154 rather than on the side of the second lower electrode 192.

The second dielectric layer 194 may include a portion 194a covering (or overlapping) a portion of a sidewall of the isolation insulating layer 152, and here, the portion 194a may contact the common plate 154. Similarly, the first dielectric layer 144 may also include a portion 144a covering (or overlapping) a portion of a sidewall of the isolation insulating layer 152, and the portion 114a may also be in contact with the common plate 154. Also, the isolation insulating layer 152 may be formed through (e.g., may extend through or may penetrate) the common plate 154 (in the vertical direction).

FIG. 4B is an enlarged view of a semiconductor memory device 20 according to some embodiments, which is an enlarged view of a portion corresponding to the portion P1 of FIG. 3. The semiconductor memory device 20 shown in FIG. 4B is substantially the same or similar to the semiconductor memory device 10 shown in FIG. 4A, except that a shape of an isolation insulating layer 252 is different from the shape of the isolation insulating layer 152 of the semiconductor memory device 10. Therefore, the description of the components already given above with reference to FIGS. 3 and 4A may be omitted or simplified.

Referring to FIG. 4B, an upper surface of the isolation insulating layer 252 may be at the same vertical level as (e.g., coplanar with) that of the upper surface of the common plate 154, and a lower surface of the isolation insulating layer 252 is at the same vertical level as (e.g., coplanar with) that of the lower surface of the common plate 154. Unlike the isolation insulating layer 152 shown in FIG. 4A, the isolation insulating layer 252 shown in FIG. 4B may not contact the first dielectric layer 144 or the second dielectric layer 194.

FIG. 4C is an enlarged view of a semiconductor memory device 30 according to some embodiments, which is an enlarged view of a portion corresponding to the portion P1 of FIG. 3. The semiconductor memory device 30 shown in FIG. 4C is substantially the same as the semiconductor memory device 10 shown in FIG. 4A, except that a shape of a first dielectric layer 344 and a shape of a second dielectric layer 394 are different from the shape of the first dielectric layer 144 and the shape of the second dielectric layer 194 of the semiconductor memory device 10 in FIG. 4A. Therefore, the description of the components already given above with reference to FIGS. 3 and 4A may be omitted or simplified.

Referring to FIG. 4C, the common plate 154 may be spaced apart from the first dielectric layer 344 and/or the second dielectric layer 394. A portion 344a of the first dielectric layer 344 in contact with the isolation insulating layer 152 may be edge-filleted (e.g., edge-rounded). The portion 344a of the first dielectric layer 344 in contact with the isolation insulating layer 152 may be spaced apart from the common plate 154. Similarly, a portion 394a of the second dielectric layer 394 in contact with the isolation insulating layer 152 may be edge-filleted (e.g., edge-rounded). The portion 394a of the second dielectric layer 394 in contact with the isolation insulating layer 152 may be spaced apart from the common plate 154.

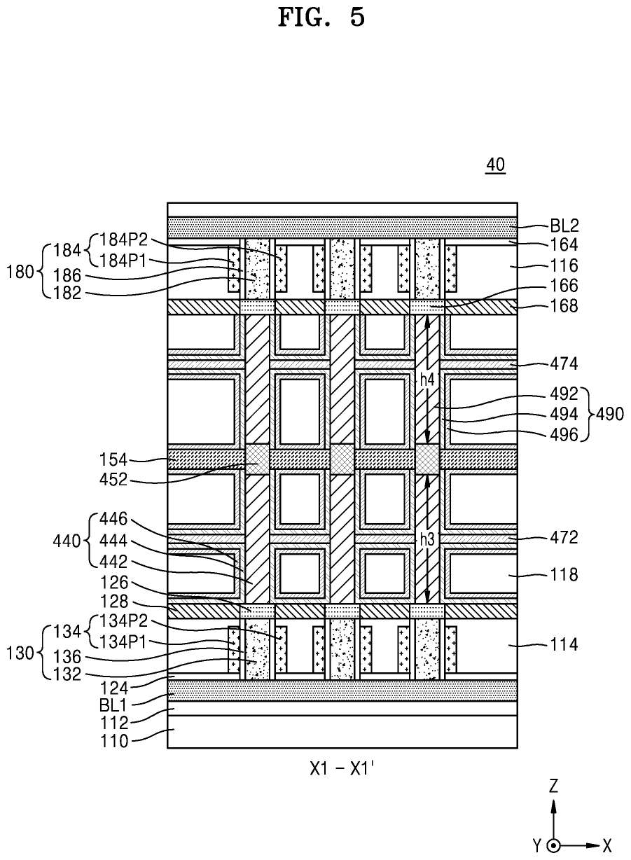

FIG. 5 is a cross-sectional view of a semiconductor memory device 40 according to some embodiments, taken along line X1-X1′ of FIG. 2. The semiconductor memory device 40 shown in FIG. 5 is substantially the same as or similar to the semiconductor memory device 10 shown in FIG. 3, except that a shape of a first lower electrode 442 and a shape of a second lower electrode 492 are different from the shape of the first lower electrode 142 and the shape of the second lower electrode 192 of the semiconductor memory device 10 in FIG. 3. Therefore, the description of the components already given above with reference to FIGS. 3 and 4A may be omitted or simplified.

Referring to FIG. 5, a first capacitor structure 440 may include the first lower electrode 442 vertically overlapping the first landing pad 126 and extending in the vertical direction (the Z direction), a first dielectric layer 444 on (e.g., covering or overlapping) a sidewall of the first lower electrode 442, and a first upper electrode 446 on (e.g., at least partially covering or overlapping) the first dielectric layer 444. A second capacitor structure 490 may include the second lower electrode 492 vertically overlapping the second landing pad 166 and extending in the vertical direction (the Z direction), a second dielectric layer 494 on (e.g., covering or overlapping) a sidewall of the second lower electrode 492, and a second upper electrode 496 on (e.g., at least partially covering or overlapping) the second dielectric layer 494.

In this case, the first lower electrode 442 and the second lower electrode 492 may have a pillar shape having a constant diameter along the vertical direction (the Z direction). A length h3 of the first lower electrode 442 in the vertical direction (the Z direction) may be the same as a length h4 of the second lower electrode 492 in the vertical direction (the Z direction). Although the length h3 of the first lower electrode 442 in the vertical direction (the Z direction) is the same as the length h4 of the second lower electrode 492 in the vertical direction (the Z direction), because a diameter of the first lower electrode 442 is the same as a diameter of the second lower electrode 492, electrical characteristics of the first capacitor structure 440 and the second capacitor structure 490 may be balanced (e.g., matched or equated).

Similarly, an isolation insulating layer 452 located between the first lower electrode 442 and the second lower electrode 492 may also have a constant diameter along the vertical direction (the Z direction). A sidewall of the first lower electrode 442, a sidewall of the second lower electrode 492, and the sidewall of the isolation insulating layer 452 may be located on (substantially) the same plane.

In addition, according to some embodiments, a vertical distance from the common plate 154 to the first support plate 472 in the vertical direction (the Z direction) may be the same as a vertical distance from the common plate 154 to the second support plate 474.

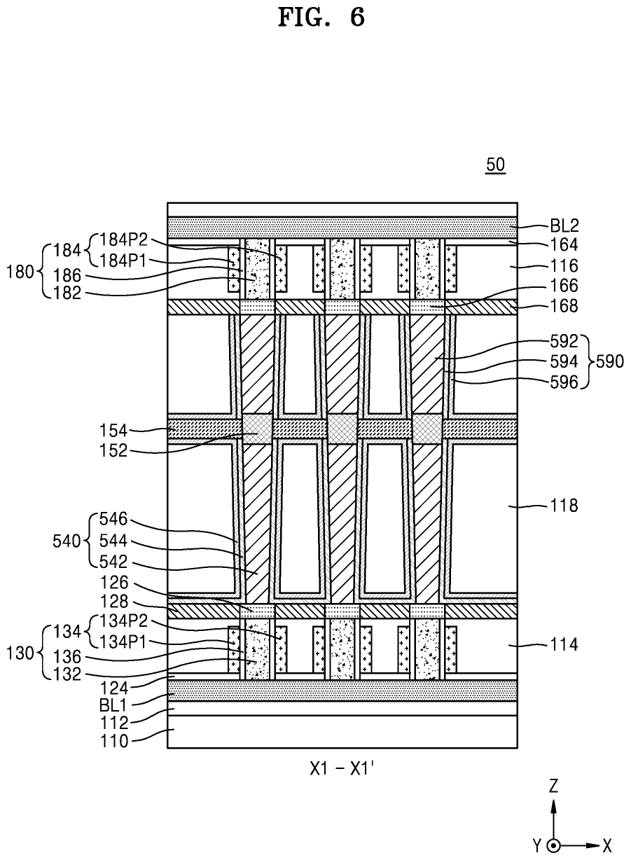

FIG. 6 is a cross-sectional view of a semiconductor memory device 50 according to some embodiments, taken along line X1-X1′ of FIG. 2. The semiconductor memory device 50 shown in FIG. 6 is substantially the same or similar to the semiconductor memory device 10 shown in FIG. 3, except that a first lower electrode 542 and a second lower electrode 592 are formed without a support plate. Therefore, the description of the components already given above with reference to FIGS. 3 and 4A may be omitted or simplified.

Referring to FIG. 6, a first capacitor structure 540 may include the first lower electrode 542 vertically overlapping the first landing pad 126 and extending in the vertical direction (the Z direction), a first dielectric layer 544 on (e.g., covering or overlapping) a sidewall of the first lower electrode 542, and a first upper electrode 546 on (e.g., at least partially covering or overlapping) the first dielectric layer 544. A second capacitor structure 590 may include the second lower electrode 592 vertically overlapping the second landing pad 166 and extending in the vertical direction (the Z direction), a second dielectric layer 594 on (e.g., covering or overlapping) a sidewall of the second lower electrode 592, and a second upper electrode 596 on (at least partially covering or overlapping) the second dielectric layer 594.

The first lower electrode 542 may extend in the vertical direction (the Z direction) from the isolation insulating layer 152 to the first landing pad 126, without being supported by an insulating plate, such as a support plate (e.g., the first support plate 172 or the second support plate 174). Similarly, the second lower electrode 592 may extend from the second landing pad 166 to the isolation insulating layer 152 in the vertical direction (the Z direction), without being supported by an insulating plate, such as a support plate (e.g., the first support plate 172 or the second support plate 174).

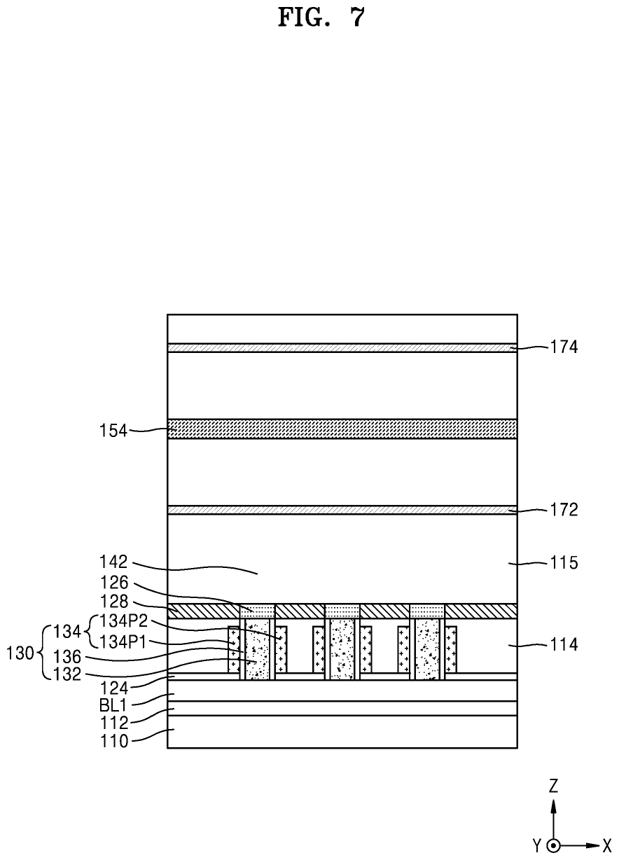

FIGS. 7 to 17 are cross-sectional views illustrating a method of manufacturing the semiconductor memory device shown in FIGS. 1 to 3.

Referring to FIG. 7, the method of manufacturing a semiconductor memory device according to some embodiments may include stacking the lower insulating layer 112 in contact with the upper surface of the substrate 110, forming the first bit lines BL1 spaced apart from each other in the second horizontal direction (the Y direction) and extending in the first horizontal direction (the X direction) on the lower insulating layer 112, and subsequently forming the first vertical transistor 130, a sacrificial layer 115, and the common plate 154 on the first bit lines BL1.

In some embodiments, the first landing pad 126 and the first upper insulating layer 128 may be located between the lowermost surface of the sacrificial layer 115 and the first vertical transistor 130. The first landing pad 126 may vertically overlap the first channel layer 132 and the first gate insulating layer 136 of the first vertical transistor 130. A first support plate 172 and a second support plate 174 extending in a direction parallel to the upper surface of the substrate 110 may be located inside the sacrificial layer 115. The first support plate 172 may be located between the common plate 154 and the first vertical transistor 130, and the second support plate 174 may be located on the common plate 154.

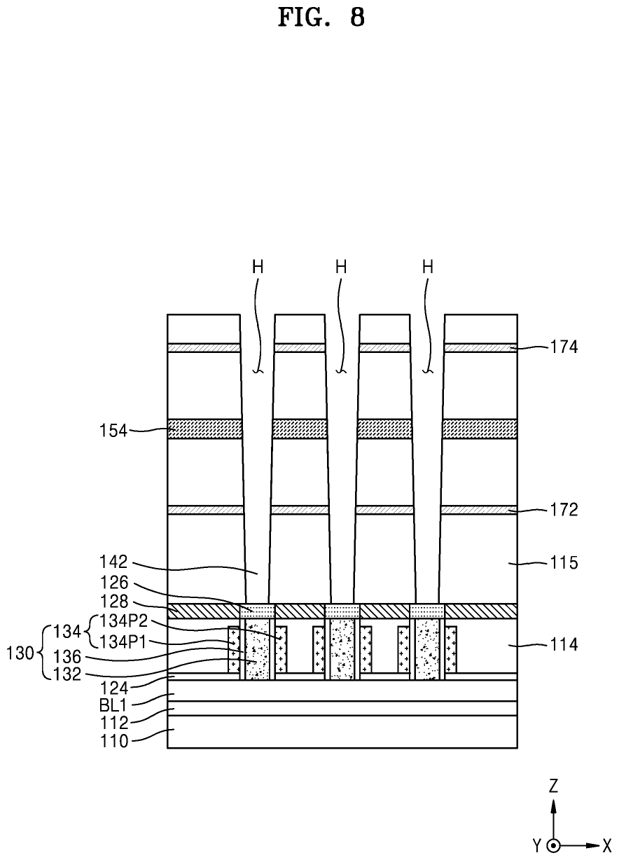

Referring to FIG. 8, the method of manufacturing a semiconductor memory device according to some embodiments may include etching the sacrificial layer 115, the first support plate 172, the common plate 154, and the second support plate 174 to form a plurality of holes H. Here, the holes H may pass through (e.g., extend through or penetrate) each of the sacrificial layer 115, the first support plate 172, the common plate 154, and the second support plate 174 to reach the first landing pad 126. For example, at least a portion of the upper surface of the first landing pad 126 may be exposed by the holes H. The etching process of forming the holes H may be a process using an etching selectivity, and the first landing pad 126 may be used as an etch stop layer. The holes H may have a tapered shape having a diameter narrowing (decreasing) toward the first landing pad 126 in the vertical direction (the Z direction).

The holes H may be formed by a process of forming a mask pattern (not shown) on an upper surface of the sacrificial layer 115 and subsequently anisotropic-etching the sacrificial layer 115, the first support plate 172, the common plate 154, and the second support plate 174 by using the mask pattern (not shown) as an etching mask and the first landing pad 126 as an etch stop layer.

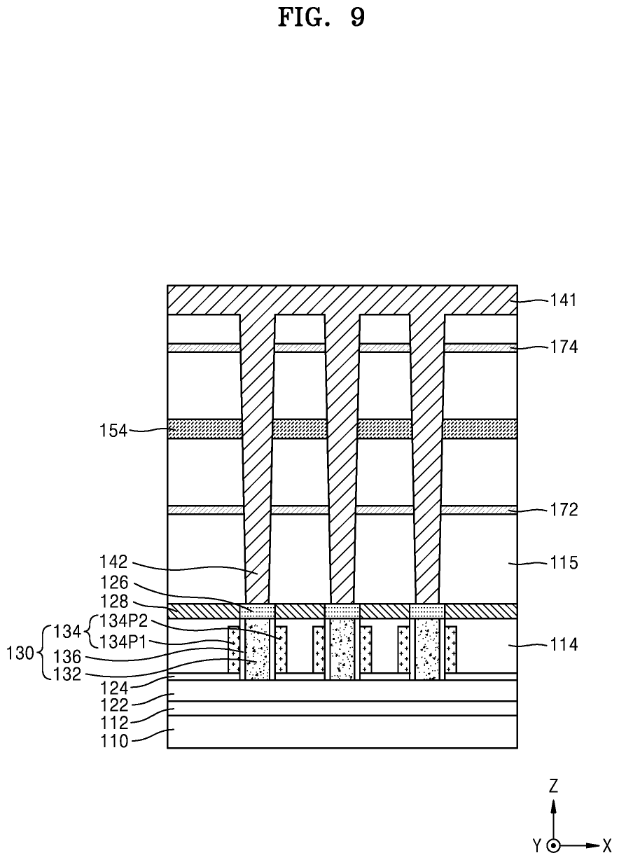

Referring to FIG. 9, in the method of manufacturing a semiconductor memory device according to some embodiments, a conductive layer 141 (at least partially) covering (or overlapping) the upper surface of the first landing pad 126, while (at least partially) filling the holes H, may be formed. In order to form the conductive layer 141, a chemical vapor deposition (CVD) process, a plasma enhanced chemical vapor deposition (PECVD) process, a metal organic CVD (MOCVD) process, and/or an atomic layer deposition (ALD) process may be used.

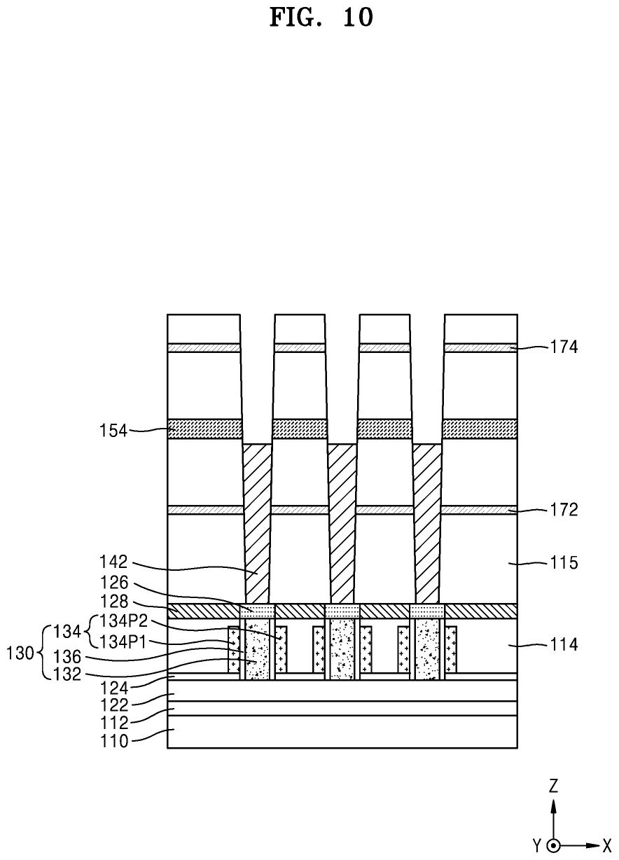

Referring to FIG. 10, the method of manufacturing a semiconductor memory device according to some embodiments may include removing a portion of the conductive layer 141 using an etch back process and/or a chemical mechanical polishing (CMP) process to form the first lower electrode 142. Here, a vertical level of the upper surface of the conductive layer 141 may be lower than a vertical level of the lower surface of the common plate 154. When the process of removing a portion of the conductive layer 141 is completed, the first lower electrode 142 vertically overlapping the first landing pad 126 and extending in the vertical direction (the Z direction) may be formed.

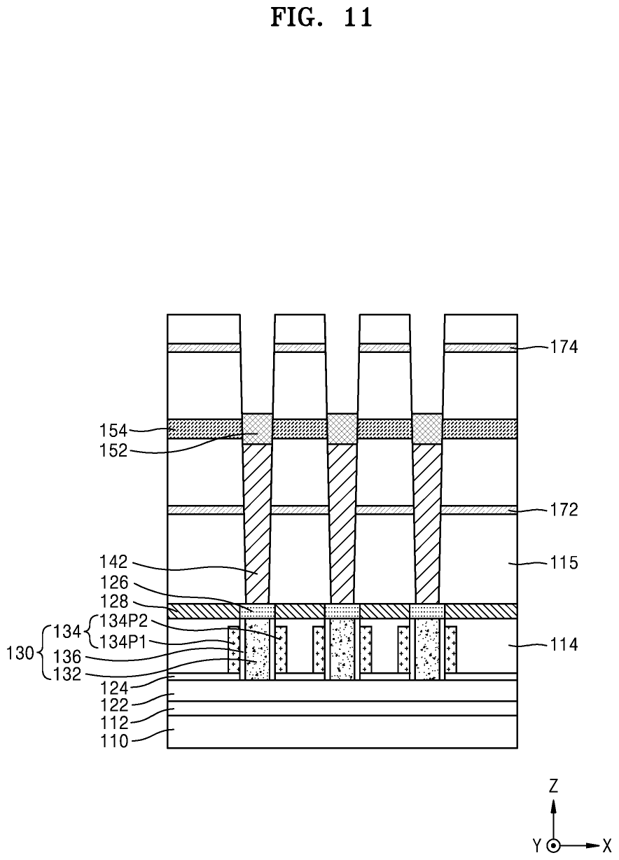

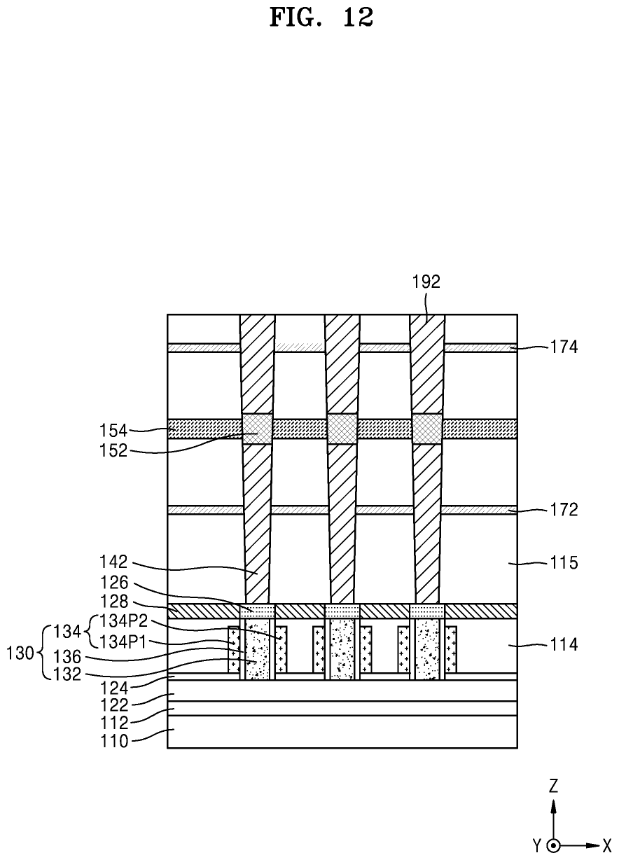

Referring to FIGS. 11 and 12, the method of manufacturing a semiconductor memory device according to some embodiments may include forming an isolation insulating layer 152 on the first lower electrode 142. Thereafter, the method of manufacturing a semiconductor memory device according to some embodiments may include forming the second lower electrode 192 on the isolation insulating layer 152. A vertical level of the upper surface of the second lower electrode 192 may be (substantially) the same as a vertical level of the upper surface of the sacrificial layer 115. For example, the upper surface of the second lower electrode 192 may be coplanar with the upper surface of the sacrificial layer 115.

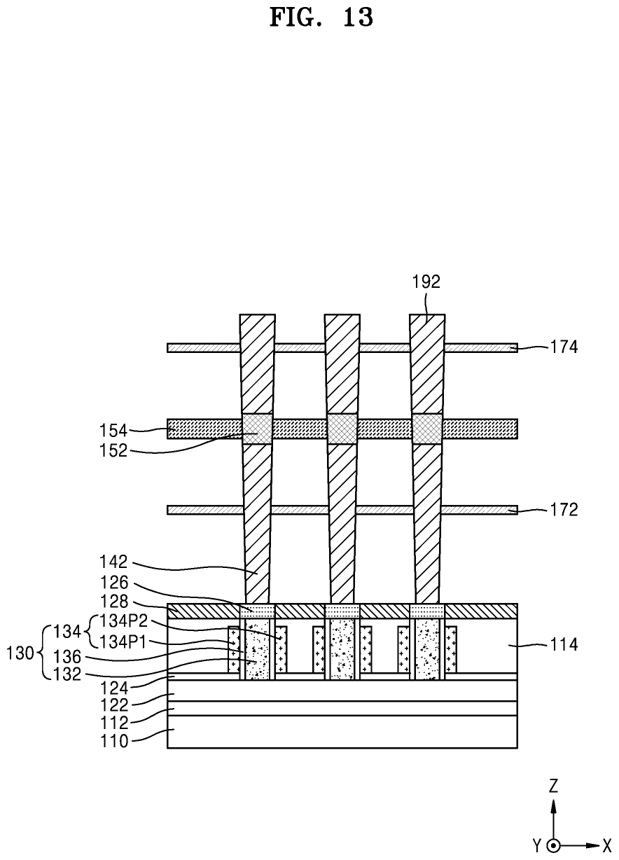

Referring to FIG. 13, the method of manufacturing a semiconductor memory device according to some embodiments may include removing the sacrificial layer 115. The process of removing the sacrificial layer 115 may be performed through, for example, a wet removal process. In order to remove the sacrificial layer 115 through the wet removal process, an etchant containing, for example, ammonium fluoride (NH₄F), hydrofluoric acid (HF), and water may be used but is not limited thereto. Sidewalls of the first lower electrode 142 and the second lower electrode 192 may be exposed through the process of removing the sacrificial layer 115. In addition, through the process of removing the sacrificial layer 115, the upper and lower surfaces of the common plate 154, the upper and lower surfaces of the first support plate 172, and the upper and lower surfaces of the second support plate 174 may be exposed.

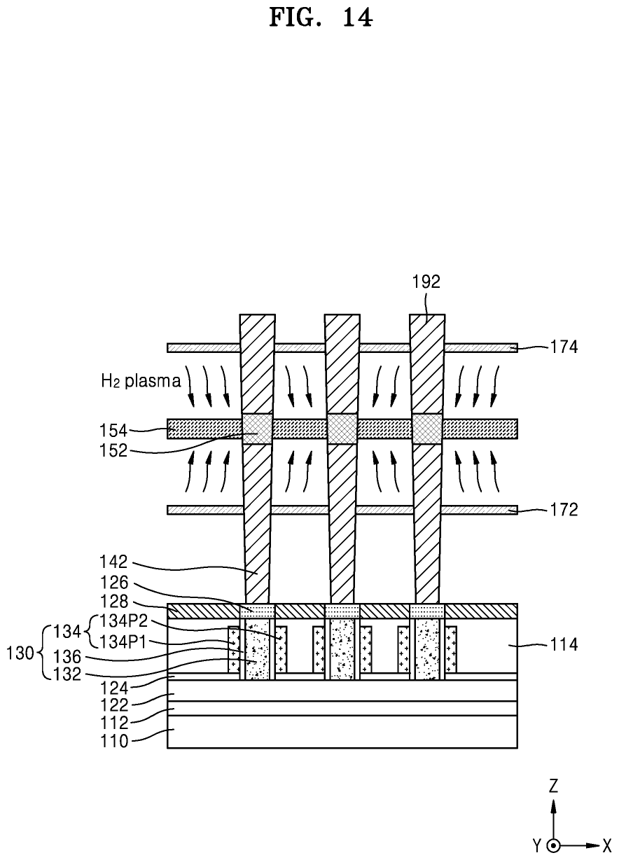

Referring to FIG. 14, the method of manufacturing a semiconductor memory device according to some embodiments may include performing a hydrogen plasma treatment on the exposed upper and lower surfaces of the common plate 154. When the hydrogen plasma treatment is applied to the surface of the common plate 154 including a carbon electrode, a dielectric material may grow slowly on the surface of the common plate 154. For example, when the hydrogen plasma treatment is applied to the surface of the common plate 154 including the carbon electrode, a dielectric material including Hf may not grow easily on the surface of the common plate 154. In some embodiments, when the hydrogen plasma treatment is applied to the surface of the carbon electrode, carbons are all replaced with sp3 bonds so that no surface reactive groups exist, and thus, the growth of HfO₂ may be restricted. The growth of a dielectric film material on the surface of the carbon electrode may be restricted by the same principle even when a chloride-based source, as well as an oxide-based source, is used.

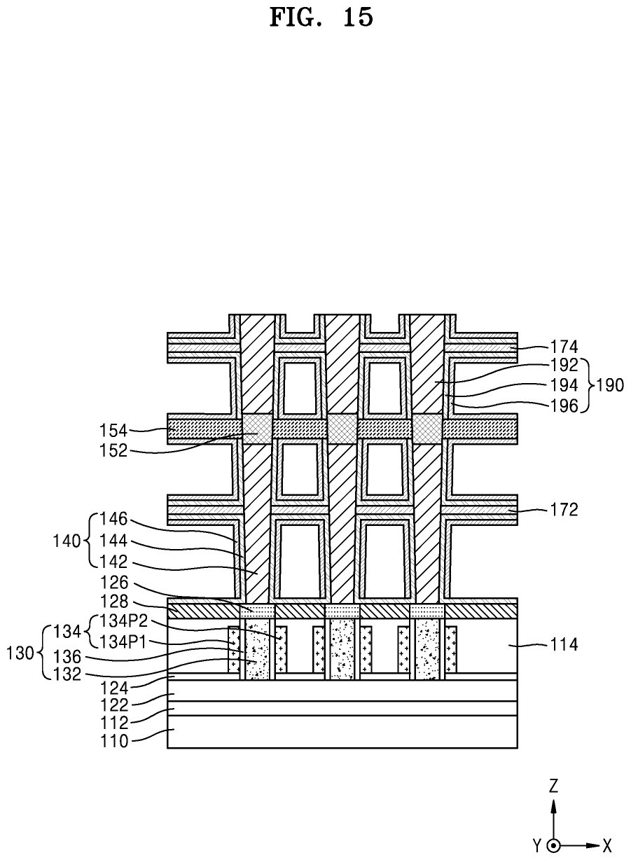

Referring to FIG. 15, the method of manufacturing a semiconductor memory device according to some embodiments may include forming the first and second dielectric layers 144 and 194 on the first and second lower electrodes 142 and 192 and forming the first and second upper electrodes 146 and 196 on the first and second dielectric layers 144 and 194 and the common plate 154. In this case, because the surface of the common plate 154 is treated with hydrogen plasma, the formation of the first dielectric layer 144 and the second dielectric layer 194 on the surface of the common plate 154 may be limited. For example, the first and second dielectric layers 144 and 194 may be on a small portion (e.g., no portion) of the surface of the common plate 154.

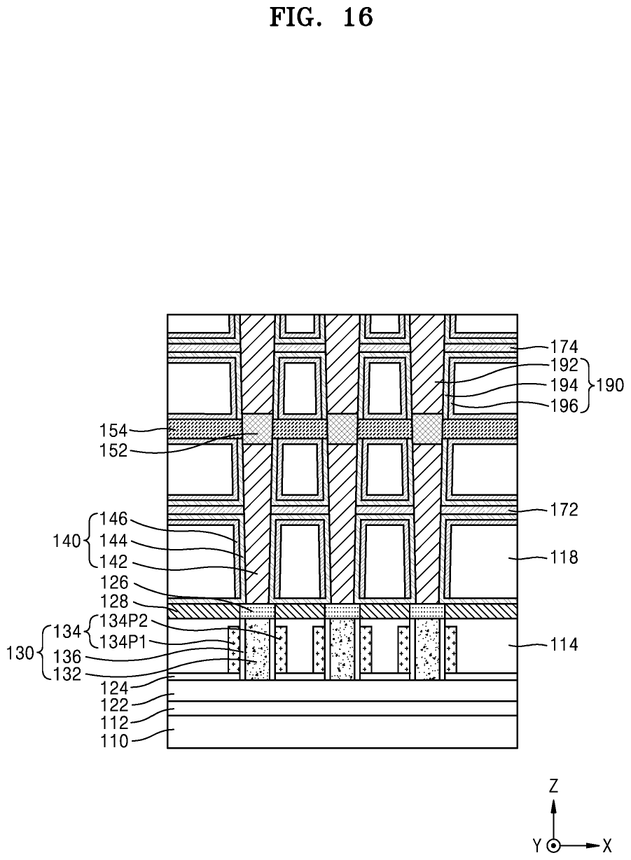

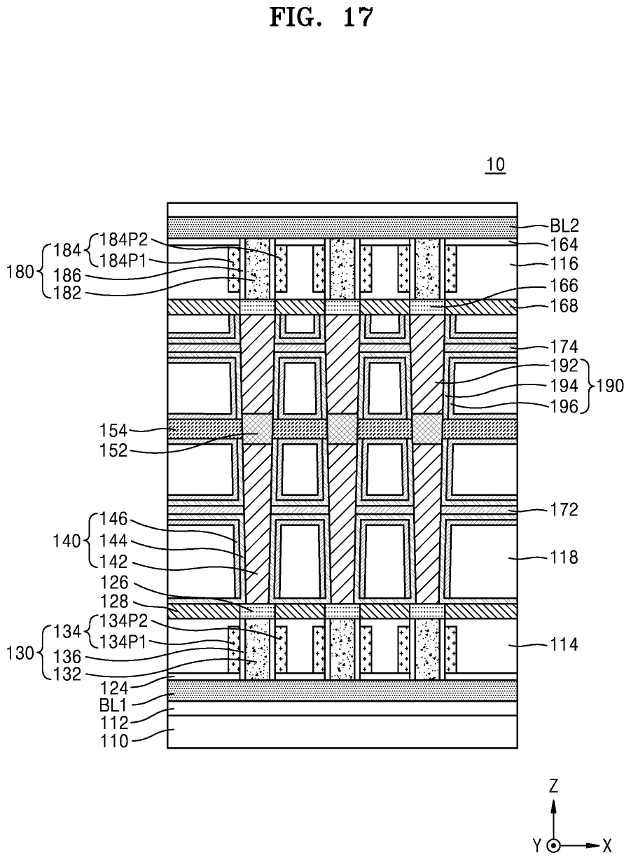

Referring to FIGS. 16 and 17, the method of manufacturing a semiconductor memory device according to some embodiments may include forming the third buried insulating layer 118 filling a space between the first and second upper electrodes 146 and 196 through a subsequent deposition process. After the third buried insulating layer 118 is formed, the second landing pad 166 vertically overlapping the second lower electrode 192 and the second upper insulating layer 168 covering (or overlapping) the side surface of the second landing pad 166 may be formed on the second capacitor structure 190. Thereafter, the second vertical transistor 180, the second buried layer 164, and the second bit line BL2 may be sequentially formed on the second landing pad 166 and the second upper insulating layer 168 to complete the semiconductor memory device 10.

While the inventive concept of the present disclosures has been particularly shown and described with reference to embodiments thereof, it will be understood that various changes in form and details may be made therein without departing from the spirit and scope of the following claims.

What is claimed is:

1. An integrated circuit device comprising:
a substrate;
a first vertical transistor on an upper surface of the substrate;
a second vertical transistor on the first vertical transistor, wherein the first vertical transistor and the second vertical transistor are spaced apart from each other in a first direction that is perpendicular to the upper surface of the substrate;
a common plate between the first vertical transistor and the second vertical transistor, wherein the common plate extends in a second direction that is parallel with the upper surface of the substrate;
a first capacitor structure between the first vertical transistor and the common plate, wherein the first capacitor structure includes a first lower electrode that extends in the first direction, a first dielectric layer on the first lower electrode, and a first upper electrode on the first dielectric layer; and
a second capacitor structure between the second vertical transistor and the common plate, wherein the second capacitor structure includes a second lower electrode that extends in the first direction, a second dielectric layer on the second lower electrode, and a second upper electrode on the second dielectric layer,
wherein the first upper electrode is on a lower surface of the common plate, and the second upper electrode is on an upper surface of the common plate.

2. The integrated circuit device of claim 1, wherein
the lower surface of the common plate includes a first lower surface that is in contact with the first dielectric layer and a second lower surface that is in contact with the first upper electrode, and
a first area of the first lower surface is less than a second area of the second lower surface.

3. The integrated circuit device of claim 1, wherein the common plate is spaced apart from the first dielectric layer.

4. The integrated circuit device of claim 1, wherein the first lower electrode has a tapered shape that has a diameter that decreases toward the substrate in the first direction.

5. The integrated circuit device of claim 1, wherein the first lower electrode has a pillar shape with a constant diameter along the first direction.

6. The integrated circuit device of claim 1, wherein the common plate includes a carbon electrode and is electrically connected to the first upper electrode and the second upper electrode.

7. The integrated circuit device of claim 1, further comprising:
a landing pad between the first vertical transistor and the first capacitor structure,
wherein an upper surface of the landing pad is in contact with a lower surface of the first lower electrode, and
wherein an area of the upper surface of the landing pad is greater than an area of the lower surface of the first lower electrode.

8. The integrated circuit device of claim 1, further comprising:
a support plate between the substrate and the common plate,
wherein the support plate extends in the second direction, and
wherein the first lower electrode extends in the support plate in the first direction.

9. An integrated circuit device comprising:
a substrate;
a first bit line that extends in a first direction on an upper surface of the substrate;
a second bit line that extends in the first direction on the first bit line;
a common plate between the first bit line and the second bit line;
a first vertical transistor between the first bit line and the common plate;
a second vertical transistor between the second bit line and the common plate;
a first capacitor structure between the first vertical transistor and the common plate;
a second capacitor structure between the second vertical transistor and the common plate; and
an isolation insulating layer that extends in the common plate in a second direction and separates the first capacitor structure and the second capacitor structure from each other,
wherein the first capacitor structure includes:
a first lower electrode that extends in the second direction between the isolation insulating layer and the first vertical transistor;
a first dielectric layer on a sidewall of the first lower electrode; and
a first upper electrode on a sidewall of the first dielectric layer and a lower surface of the common plate,
wherein the second direction is perpendicular to the upper surface of the substrate,
wherein the first direction is parallel with the upper surface of the substrate,
wherein the lower surface of the common plate is in contact with the first upper electrode, and
wherein the first dielectric layer includes a ferroelectric material.

10. The integrated circuit device of claim 9, wherein
the second capacitor structure includes:
a second lower electrode that extends in the second direction between the second vertical transistor and the isolation insulating layer;
a second dielectric layer on a sidewall of the second lower electrode; and
a second upper electrode on a sidewall of the second dielectric layer and an upper surface of the common plate,
wherein the upper surface of the common plate is in contact with the second upper electrode.

11. The integrated circuit device of claim 10, further comprising:
a first support plate between the first vertical transistor and the common plate, wherein the first support plate extends in the first direction; and
a second support plate between the second vertical transistor and the common plate, wherein the second support plate extends in the first direction,
wherein the first lower electrode extends in the first support plate, and
the second lower electrode extends in the second support plate.

12. The integrated circuit device of claim 10, wherein a first length of the first lower electrode in the second direction is greater than a second length of the second lower electrode in the second direction.

13. The integrated circuit device of claim 10, wherein
the first lower electrode has a pillar shape with a first diameter that is constant along the second direction,
the second lower electrode has a pillar shape with a second diameter that is constant along the second direction,
the first diameter is equal to the second diameter, and
a first length of the first lower electrode in the second direction is equal to a second length of the second lower electrode in the second direction.

14. The integrated circuit device of claim 10, wherein the sidewall of the first lower electrode, the sidewall of the second lower electrode, and a sidewall of the isolation insulating layer are on a same plane without a step difference.

15. The integrated circuit device of claim 10, wherein the common plate includes a carbon electrode and is electrically connected to the first upper electrode and the second upper electrode.

16. The integrated circuit device of claim 9, wherein a length of the isolation insulating layer in the second direction is equal to a length of the common plate in the second direction.

17. The integrated circuit device of claim 9, wherein
a portion of the first dielectric layer overlaps a portion of a sidewall of the isolation insulating layer in the first direction, and
the portion of the first dielectric layer is in contact with the common plate.

18. The integrated circuit device of claim 9, wherein a portion of the first dielectric layer is in contact with a portion of the isolation insulating layer, and the portion of the first dielectric layer is spaced apart from the common plate.

19. An integrated circuit device comprising:
a substrate;
a first bit line that extends in a first direction on an upper surface of the substrate;
a second bit line that extends in the first direction on the first bit line;
a common plate between the first bit line and the second bit line, wherein the common plate extends in the first direction;
a plurality of first vertical transistors between the first bit line and the common plate;
a plurality of second vertical transistors between the second bit line and the common plate;
a first capacitor structure between one of the plurality of first vertical transistors and the common plate;
a second capacitor structure between one of the plurality of second vertical transistors and the common plate; and
an isolation insulating layer between the first capacitor structure and the second capacitor structure, wherein the isolation insulating layer extends through the common plate in a second direction and separates the first capacitor structure and the second capacitor structure from each other,
wherein the first capacitor structure includes:
a plurality of first lower electrodes that extend in the second direction between the isolation insulating layer and the plurality of first vertical transistors and are arranged in the first direction, wherein each of the plurality of first lower electrodes has a tapered shape with a first diameter that decreases toward the plurality of first vertical transistors;
a first dielectric layer on a sidewall of each of the plurality of first lower electrodes, wherein the first dielectric layer includes a ferroelectric material; and
a first upper electrode on a sidewall of the first dielectric layer and a portion of a lower surface of the common plate,
wherein the first upper electrode is in contact with the lower surface of the common plate, and
wherein the second capacitor structure includes:
a plurality of second lower electrodes that extend in the second direction between the isolation insulating layer and the plurality of second vertical transistors and are arranged in the first direction, wherein each of the plurality of second lower electrodes has a tapered shape with a second diameter that decreases toward the isolation insulating layer;
a second dielectric layer on a sidewall of each of the plurality of second lower electrodes, wherein the second dielectric layer includes a ferroelectric material; and
a second upper electrode on a sidewall of the second dielectric layer and a portion of an upper surface of the common plate,
wherein the second upper electrode is in contact with the upper surface of the common plate
wherein the second direction is perpendicular to the upper surface of the substrate, and
wherein the first direction is parallel with the upper surface of the substrate.

20. The integrated circuit device of claim 19, wherein
the one of the plurality of first vertical transistors includes:
a first channel layer, wherein a length in the second direction of the first channel layer is greater than a width of the first channel layer in the first direction; and
first gate electrodes on opposite sidewalls of the first channel layer, wherein the first gate electrodes extend in a third direction that is parallel with the upper surface of the substrate and perpendicular to the first direction, and
the one of the plurality of second vertical transistors includes:
a second channel layer, wherein a length in the second direction of the second channel layer is greater than a width of the second channel layer in the first direction; and
second gate electrodes on opposite sidewalls of the second channel layer, wherein the second gate electrodes extend in the third direction.
